(19) United States
(12) Patent Application Publication
(10) Pub. No.: US 2009/0079609 A1
(43) Pub. Date: Mar. 26, 2009

(54) Digital-to-analog converter

(75) Inventor: Chin-Hung Hsu, Taoyuan County (TW)

Correspondence Address: RABIN & Berdo, PC, 1101 14TH STREET, NW, SUITE 500, WASHINGTON, DC, 20005, US

(73) Assignee: NOVATEK MICROELECTRONICS CORP., Hsinchu (TW)

(21) Appl. No.: 12/007,202

(22) Filed: Jan. 8, 2008

(30) Foreign Application Priority Data
Sep. 20, 2007 (TW) 096135228

(51) Int. Cl. H03M 1/66

(52) U.S. Cl. 341/144

(57) ABSTRACT

A digital-to-analog converter for converting a digital signal into an analog voltage is provided. The digital-to-analog converter includes a first series of resistors, a first cascade of switches, a second series of resistors and a second cascade of switches. The first series of resistors comprising a first resistor and a second resistor is electrically connected between a first voltage and an output terminal of the digital-to-analog converter. The first cascade of switches comprising a first switch and a second switch is controlled by the digital signal. The second series of resistors comprising a first matching resistor and a second matching resistor is electrically connected between a second voltage and the output terminal. The second cascade of switches comprising a first matching switch and a second matching switch is controlled by an inversion signal of the digital signal. The digital-to-analog converter outputs the analog voltage via the output terminal.

This application claims the benefit of Taiwan application Serial No. 96135228, filed Sep. 20, 2007, the subject matter of which is incorporated herein by reference.

### BACKGROUND OF THE INVENTION

1. Field of the Invention

The invention relates in general to a digital-to-analog converter, and more particularly to a digital-to-analog converter with simple circuit structure.

2. Description of the Related Art

Referring to FIG. 1, a circuit diagram of a conventional digital-to-analog converter is shown. The digital-to-analog converter 100 is exemplified by a 4-bit digital-to-analog converter. The digital-to-analog converter 100 includes a series of resistors and many switches, wherein a terminal of the series of resistors is electrically connected to a first voltage V1, and the other terminal of the series of resistors is electrically connected to a second voltage V2. The series of resistors includes many resistors R₀ to R₁₄ connected in serial, wherein the resistance of each resistor is equal to R. The many switches are respectively controlled by many control signals C₀ to C₃ and MC₀ to MC₃ corresponding to the bit values and the complementary values of the digital signal (B₃B₂B₁B₀)₂. When the bit value equals “1”, the voltage level of the control signal corresponding to the bit value is at a high voltage level. When the bit value equals “0”, the voltage level of the control signal corresponding to the bit value is at a low voltage level.

Let the digital signal (B₃B₂B₁B₀)₂ be (1100)₂. When the digital signal (B₃B₂B₁B₀)₂ is (1100)₂, the complementary values ( B̅₃̅ B̅₂̅ B̅₁̅ B̅₀̅)₂ of the bit values are (0011)₂. Based on the many control signals C₀ to C₃ and MC₀ to MC₃ corresponding to the bit values and the complementary values of the digital signal (B₃B₂B₁B₀)₂, the switches MSW₀, MSW₁, SW₂ and SW₃ are turned on. The digital-to-analog converter 100, via the path (1) of FIG. 1, converts the digital signal (1100)₂ into an analog voltage Vout and outputs the analog voltage Vout via an output terminal OUT. The analog voltage Vout is actually the voltage at the node P of the voltage-division circuit constituted by the first voltage V1, the second voltage V2 and many resistors R₀ to R₁₄. However, as each node of the series of resistors of the voltage-division circuit is connected to a wire in the circuit layout and there are 2⁴ nodes existing in the series of resistors of the digital-to-analog converter 100, totally, 2⁴=16 wires and (2⁴⁺¹−2)=30 switches are needed.

As the digital-to-analog converter adopts higher bits, the number of wires will be increased dramatically if conventional digital-to-analog converter is used. The n-bit digital-to-analog converter needs 2ⁿ wires to electrically connected to 2ⁿ nodes. As a result, a large area of circuit layout will be occupied, and the chip area of the digital-to-analog converter also increases greatly. Moreover, the series of resistors needs (2ⁿ−1) resistors with corresponding to (2ⁿ⁺¹−2) switches. Too many wires, switches and resistors would make high-bit digital-to-analog converter hard to be embodied.

### SUMMARY OF THE INVENTION

The invention is directed to a digital-to-analog converter with a simple circuit structure so that the areas of circuit layout and chips are reduced and a high-bit digital-to-analog converter is easier to be realized.

According to a first aspect of the present invention, a digital-to-analog converter for converting a digital signal into an analog voltage is provided. The digital signal includes at least a first bit value and a second bit value, wherein the first bit value is a low-bit value. The digital-to-analog converter includes a first series of resistors, a first cascade of switches, a second series of resistors and a second cascade of switches. The first series of resistors is electrically connected between a first voltage and an output terminal of the digital-to-analog converter. The first series of resistors includes at least a first resistor and a second resistor, wherein the resistance of the second resistor is substantially double of the resistance of the first resistor. The first resistor is serially coupled to the second resistor. The first cascade of switches includes at least a first switch and a second switch, wherein the first switch and the first resistor are connected in parallel and so are the second switch and the second resistor connected in parallel. The first switch is controlled by a first control signal corresponding to the first bit value; the second switch is controlled by a second control signal corresponding to the second bit value. The second series of resistors including at least a first matching resistor and a second matching resistor is electrically connected between a second voltage and the output terminal, wherein the resistance of the first matching resistor is substantially equal to the resistance of the first resistor, and the resistance of the second matching resistor is substantially equal to the resistance of the second resistor. The first matching resistor is serially coupled to the second matching resistor. The second cascade of switches includes at least a first matching switch and a second matching switch, wherein the first matching switch and the first matching resistor are connected in parallel and so are the second matching switch and the second matching resistor connected in parallel. The first matching switch is controlled by a first matching control signal corresponding to the complementary value of the first bit value; the second matching switch is controlled by a second matching control signal corresponding to the complementary value of the second bit value. The digital-to-analog converter outputs the analog voltage via the output terminal.

According to a second aspect of the present invention, a digital-to-analog converter for converting a digital signal into an analog voltage is provided. The digital signal is expressed as (Bₙ₋₁ . . . B₂ B₁ B₀)₂. The digital-to-analog converter includes a first series of resistors, a first cascade of switches, a second series of resistors and a second cascade of switches. The first series of resistors is electrically connected between a first voltage and an output terminal of the digital-to-analog converter. The first series of resistors includes n resistors R₀, R₁, R₂, . . . Rₙ₋₁ whose resistances are substantially equal to R, 2R, 2²R, . . . 2ⁿ⁻¹R respectively, wherein R is the resistance of the resistor R₀. The n resistors R₀, R₁, R₂, . . . Rₙ₋₁ are connected in serial. The first cascade of switches includes n switches SW₀, SW₁, SW₂, . . . SWₙ₋₁, wherein the n switches SW₀, SW₁, SW₂ . . . SWₙ₋₁ and the n resistors R₀, R₁, R₂, . . . Rₙ₋₁ are connected in parallel respectively. The n switches SW₀, SW₁, SW₂, . . . SWₙ₋₁ are respectively controlled by n control signals corresponding to the n bit values B₀, B₁, B₂, . . . Bₙ₋₁ respectively. The second series of resistors is electrically connected between a second voltage and an output terminal. The second series of resistors includes n matching resistors MR₀, MR₁, MR₂, . . . MRₙ₋₁ whose resistances are substantially equal to the resistances of the n resistors R₀, R₁, R₂ . . . Rₙ₋₁ respectively. The n matching resistors MR₀, MR₁, MR₂ . . . MRₙ₋₁ are connected in serial. The second cascade of switches includes n matching switches MSW₀, MSW₁, MSW₂, . . . MSWₙ₋₁, wherein the n matching switches MSW₀, MSW₁, MSW₂, . . . MSWₙ₋₁, and the n matching resistors MR₀, MR₁, MR₂, . . . MRₙ₋₁ are connected in parallel respectively. The n matching switches MSW₀, MSW₁, MSW₂, . . . MSWₙ₋₁ are respectively controlled by n matching control signals respectively corresponding to the complementary values of the n bit values B₀, B₁, B₂, . . . Bₙ₋₁. The digital-to-analog converter outputs the analog voltage via the output terminal.

The invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a circuit diagram of a conventional digital-to-analog converter;

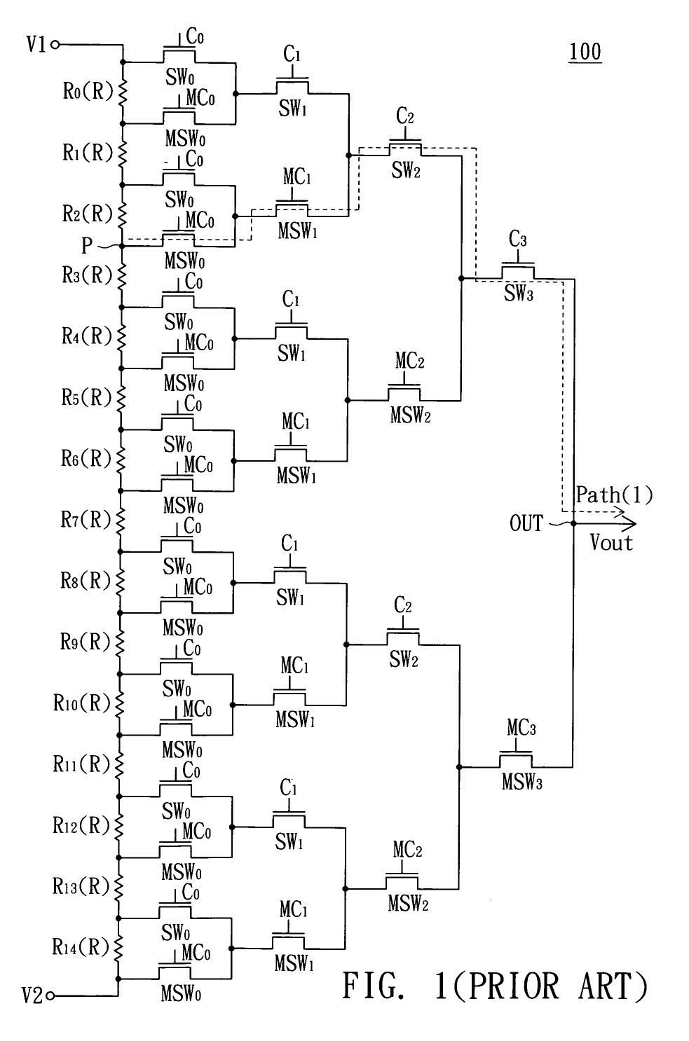

FIG. 2A is a circuit diagram of a digital-to-analog converter according to a first embodiment of the invention;

FIG. 2B is a circuit diagram of an example of the digital-to-analog converter according to the first embodiment of the invention; and

FIGS. 3A to 3C are respective circuit diagrams of a digital-to-analog converter a according to a second embodiment to a fourth embodiment of the invention.

### DETAILED DESCRIPTION OF THE INVENTION

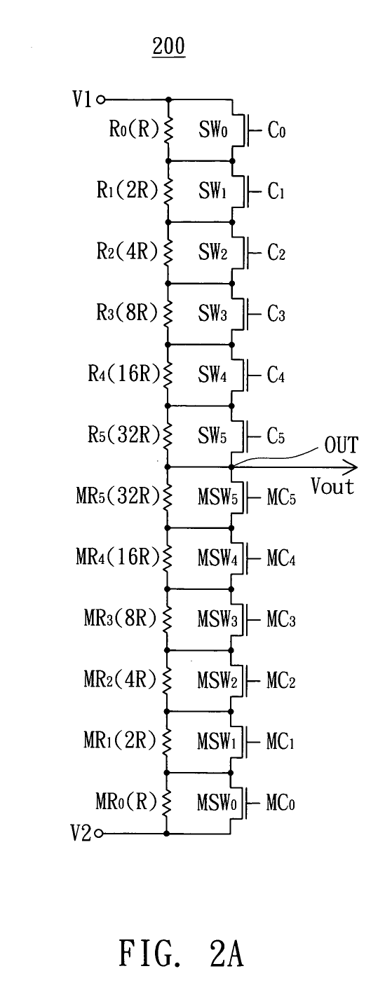

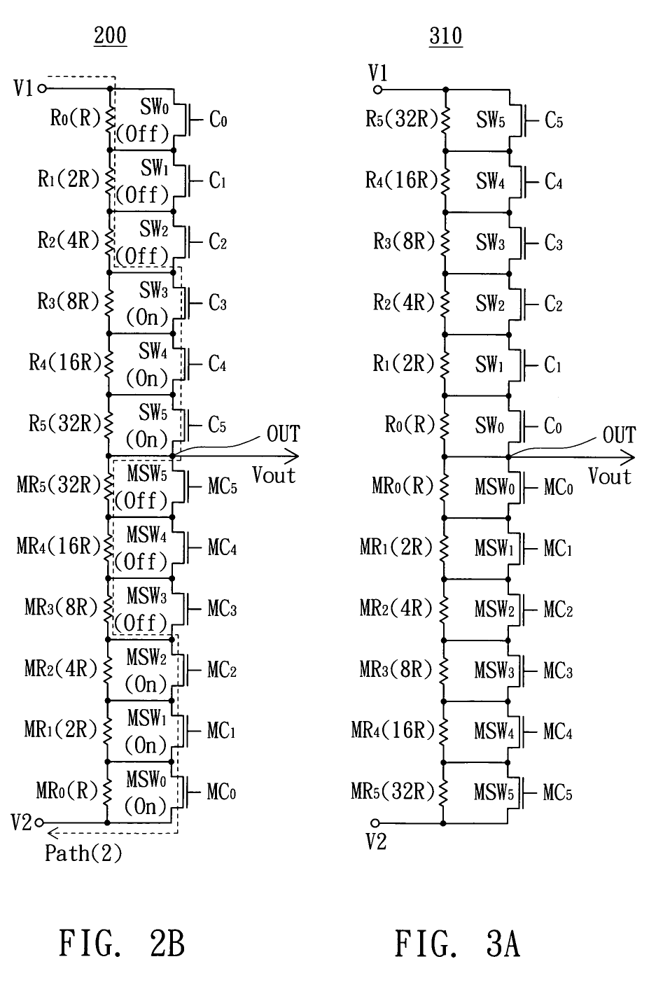

The invention provides a digital-to-analog converter with a simple circuit structure so that the areas of circuit layout and chips are reduced and a high-bit digital-to-analog converter is easier to be realized. Referring to FIG. 2A, a circuit diagram of a digital-to-analog converter according to a first embodiment of the invention is shown. In the present embodiment of the invention, the digital-to-analog converter 200 is exemplified by a 6-bit digital-to-analog converter, but is not limited thereto, and the circuit structure of the digital-to-analog converter disclosed in the invention is also applicable to other n-bit digital-to-analog converter, n is a positive integer larger than or equal to 2. For example, the digital-to-analog converter 200 is for converting a digital signal (B₅B₄B₃B₂B₁B₀)₂ into an analog voltage Vout, wherein the digital signal (B₅B₄B₃B₂B₁B₀)₂ includes 6 bit values B₀, B₁, B₂, B₃, B₄ and B₅.

The digital-to-analog converter 200 includes a first series of resistors, a first cascade of switches, a second series of resistors and a second cascade of switches. The first series of resistors is electrically connected between a first voltage V1 and an output terminal OUT of the digital-to-analog converter 200. The first series of resistors includes a first resistor R₀ to a sixth resistor R₅, wherein the first resistor R₀, the second resistor R₁, the third resistor R₂, . . . , the sixth resistor R₅ are sequentially connected in serial. The first terminal of the first resistor R₀ is electrically connected to the first voltage V1; the second terminal of the sixth resistor R₅ is electrically connected to the output terminal OUT. As the digital signal (B₅B₄B₃B₂B₁B₀)₂ is binary, the resistances of the first resistor R₀ to the sixth resistor R₅ form a geometric series whose ratio is 2. That is, (R₀, R₁, R₂, R₃, R₄, R₅) is expressed as (R, 2R, 4R, 8R, 16R, 32R).

The first cascade of switches includes a first switch SW₀ to a sixth switch SW₅ substantially and electrically connected between the first voltage V1 and the output terminal OUT of the digital-to-analog converter 200, wherein, the first switch SW₀ and the first resistor R₀, the second switch SW₁ and the second resistor R₁, the third switch SW₂ and the third resistor R₂, the fourth switch SW₃ and the fourth resistor R₃, the fifth switch SW₄ and the fifth resistor R₄, and the sixth switch SW₅ and the sixth resistor R₅ are respectively connected in parallel. Wherein the first switch SW₀ is controlled by a first control signal C₀ corresponding to the first bit value B₀, the second switch SW₁ is controlled by a second control signal C₁ corresponding to the second bit value B₁, the third switch SW₂ is controlled by a third control signal C₂ corresponding to the third bit value B₂, the fourth switch SW₃ is controlled by a fourth control signal C₃ corresponding to the fourth bit value B₃, the fifth switch SW₄ is controlled by a fifth control signal C₄ corresponding to the fifth bit value B₄, and the sixth switch SW₅ is controlled by a sixth control signal C₅ corresponding to the sixth bit value B₅. When the bit value equals “1”, the voltage level of the control signal corresponding to the bit value is at a high voltage level and the switch is turned on. When the bit value equals “0”, the voltage level of the control signal corresponding to the bit value is at a low voltage level and the switch is turned off.

The second series of resistors is electrically connected between a second voltage V2 and the output terminal OUT of the digital-to-analog converter 200. The second series of resistors includes a first matching resistor MR₀ to a sixth matching resistor MR₅, wherein the sixth matching resistor MR₅, the fifth resistor MR₄, the fourth resistor MR₃, . . . , and the first matching resistor MR₀ are sequentially connected in serial, the first terminal of the sixth matching resistor MR₅ is electrically connected to the output terminal OUT, and the second terminal of the first matching resistor MR₀ is electrically connected to the second voltage V2. Besides, the resistance of the first matching resistor MR₀ is substantially equal to the resistance of the first resistor R₀, the resistance of the second matching resistor MR₁ is substantially equal to the resistance of the second resistor R₁, the resistance of the third matching resistor MR₂ is substantially equal to the resistance of the third resistor R₂, the resistance of the fourth matching resistor MR₃ is substantially equal to the resistance of the fourth resistor R₃, the resistance of the fifth matching resistor MR₄ is substantially equal to the resistance of the fifth resistor R₄, and the resistance of the sixth matching resistor MR₅ is substantially equal to the resistance of the sixth resistor R₅. That is, (MR₀, MR₁, MR₂, MR₃, MR₄, MR₅) is expressed as (R, 2R, 4R, 8R, 16R, 32R).

The second cascade of switches includes a first matching switch MSW₀ to a sixth matching switch MSW₅ substantially and electrically connected between the second voltage V2 and the output terminal OUT of the digital-to-analog converter 200, wherein the first matching switch MSW₀ and the first matching resistor MR₀, the second matching switch MSW₁ and the second matching resistor MR₁, the third matching switch MSW₂ and the third matching resistor MR₂, the fourth matching switch MSW₃ and the fourth matching resistor MR₃, the fifth matching switch MSW₄ and the fifth matching resistor MR₄, and the sixth matching switch MSW₅ and the sixth matching resistor MR₅ are respectively connected in parallel.

The first matching switch MSW₀ is controlled by a first matching control signal MC₀ corresponding to the complementary value of the first bit value B₀. The second matching switch MSW₁ is controlled by a second matching control signal MC₁ corresponding to the complementary value of the second bit value B₁. The third matching switch MSW₂ is controlled by a third matching control signal MC₂ corresponding to the complementary value of the third bit value B₂. The fourth matching switch MSW₃ is controlled by a fourth matching control signal MC₃ corresponding to the complementary value of the fourth bit value B₃. The fifth matching switch MSW₄ is controlled by a fifth matching control signal MC₄ corresponding to the complementary value of the fifth bit value B₄. The sixth matching switch MSW₅ is controlled by a sixth matching control signal MC₅ corresponding to the complementary value of the sixth bit value B₅. When the complementary value equals “1”, the voltage level of the matching control signal corresponding to the complementary value is at a high voltage level and the switch is turned on. When the complementary value equals “0”, the voltage level of the matching control signal corresponding to the complementary value is at a low voltage level and the switch is turned off.

Of the digital-to-analog converter 200, the x-th matching switch MSWₓ substantially corresponds to the x-th switch SWₓ, wherein x is an integer ranging from 0 to 5. When the x-th switch SWₓ is turned on, the x-th matching switch MSWₓ is turned off. When the x-th switch SWₓ is turned off, the x-th matching switch MSWₓ is turned on. After the digital-to-analog converter 200 receives the digital signal (B₅B₄B₃B₂B₁B₀)₂, based on the many control signals C₀ to C₅ and the many matching control signals MC₀ to MC₅ corresponding to the bit values and the complementary values, the first voltage V1, the second voltage V2, the first series of resistors and the second series of resistors constitute a voltage-division circuit for enabling the digital-to-analog converter 200 to convert the digital signal (B₅B₄B₃B₂B₁B₀)₂ into an analog voltage Vout and output the analog voltage Vout via the output terminal OUT. Due to the correspondence between the x-th matching switch MSWₓ and the x-th switch SWₓ, the total resistance of the voltage-division circuit will remain at a fixed value so that the current flowing through the voltage-division circuit is a constant current. The analog voltage Vout outputted from the digital-to-analog converter 200 is obtained according to equation (1) expressed as below:

Vout=V2+(B₀×2⁰R+B₁×2¹R+B₂×2²R+B₃×2³R+B₄×2⁴R+B₅×2⁵R)×(V1−V2)/63R eq. (1)

Referring to Table 1, a reference table showing the correspondence between the digital signal and the analog voltage of the digital-to-analog converter according to a preferred embodiment of the invention is shown.

TABLE 1

| Digital Signal (B₅B₄B₃B₂B₁B₀) | Analog Voltage Vout |
|---|---|
| 111111 | V1 |
| 111110 | V2 + (V1 − V2) × 62/63 |
| 111101 | V2 + (V1 − V2) × 61/63 |
| 111100 | V2 + (V1 − V2) × 60/63 |
| . . . | . . . |
| 111000 | V2 + (V1 − V2) × 56/63 |
| . . . | . . . |
| 101010 | V2 + (V1 − V2) × 42/63 |
| . . . | . . . |
| 010101 | V2 + (V1 − V2) × 21/63 |
| . . . | . . . |
| 000011 | V2 + (V1 − V2) × 3/63 |
| 000010 | V2 + (V1 − V2) × 2/63 |
| 000001 | V2 + (V1 − V2) × 1/63 |
| 000000 | V2 |

Let the digital signal (B₅B₄B₃B₂B₁B₀)₂ be (111000)₂. Referring to FIG. 2B, a circuit diagram of an example of the digital-to-analog converter according to the first embodiment of the invention is shown. When the digital signal (B₅B₄B₃B₂B₁B₀)₂ is expressed as (111000)₂, the first switch SW₀, the second switch SW₁, the third switch SW₂, the fourth matching switch MSW₃, the fifth matching switch MSW₄ and the sixth matching switch MSW₅ are turned off, but the first matching switch MSW₀, the second matching switch MWS₁, the third matching switch MSW₂, the fourth switch SW₃, the fifth switch SW₄ and the sixth switch SW₅ are turned on. The first series of resistors is equivalent to a first divider resistor (R+2R+4R) and the second series of resistors is equivalent to a second divider resistor (32R+16R+8R), so the digital-to-analog converter 200, via the path (2) of FIG. 2B, converts the digital signal (111000)₂ into the analog voltage Vout and outputs the analog voltage Vout=V2+(V1−V2)×56/63 via the output terminal OUT, wherein the analog voltage Vout is relevant to 56, that is, the number denoted by the digital signal (111000)₂.

Besides, an n-bit digital-to-analog converter receives the digital signal (Bₙ₋₁ . . . B₃B₂B₁B₀)₂ and converts the digital signal (Bₙ₋₁ . . . B₃B₂B₁B₀)₂ into an analog voltage Vout obtained according to equation (2) expressed as below:

Vout=V2+(B₀×2⁰R+B₁×2¹R+B₂×2²R+B₃×2³R+ . . . +Bₙ₋₁×2ⁿ⁻¹R)×(V1−V2)/(2⁰R+2¹R+2²R+2³R+ . . . +2ⁿ⁻¹R+2ⁿ⁻¹R) eq. (2)

Of the digital-to-analog converter of the invention, there is correspondence existing between matching switches and switches. Therefore, in the voltage-division circuit, the sum of the resistances between the first voltage V1 and the second voltage V2 is constant, and the sum of the resistances of the resistors between the first voltage V1 and the output terminal OUT with currents flowing through (that is, the sum of the resistances of the resistors when the switches connected in parallel between the first voltage V1 and the output terminal OUT are turned off) is relevant to the value of the digital signal. Therefore, of the digital-to-analog converter disclosed in the invention, the resistors of the first series of resistors are not subjected to any specific sequence, and as long as all the resistors of the first series of resistors are located between the first voltage V1 and the output terminal OUT will do; likewise, the matching resistors of the second series of resistors are not subjected to any specific sequence, and as long as all the matching resistors of the second series of resistors are located between the output terminal OUT and the second voltage V2 will do. Besides, any circuit designs whose resistors or matching resistors are connected in parallel with corresponding switch or matching switch and are controlled by control signals with correspondence to corresponding bit values are within the scope of the invention.

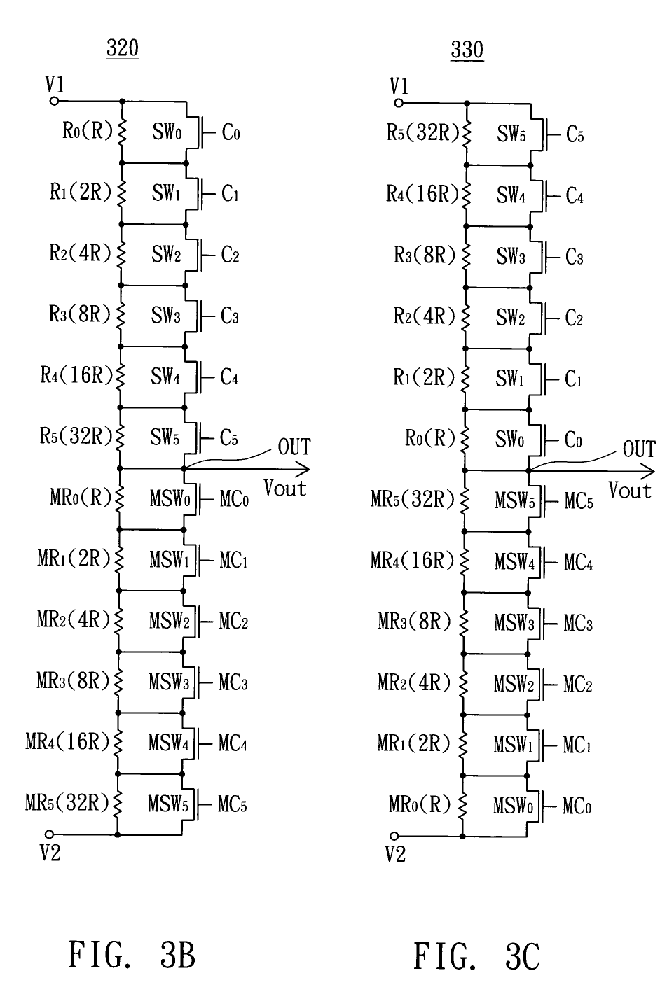

Referring to FIGS. 3A to 3C, respective circuit diagrams of a digital-to-analog converter according to a second embodiment to a fourth embodiment of the invention are shown. Of the digital-to-analog converter 310, the sixth resistor R₅, the fifth resistor R₄, the fourth resistor R₃, . . . , the first resistor R₀ are sequentially connected in serial, wherein the first terminal of the fifth resistor R₅ is electrically connected to the first voltage V1, the second terminal of the first resistor R₀t is electrically connected to the output terminal OUT. The first matching resistor MR₀, the second resistor MR₁, the third resistor MR₂, . . . , the sixth matching resistor MR₅ are sequentially connected in serial, wherein the first terminal of the first matching resistor MR₀ is electrically connected to the output terminal OUT, the second terminal of the sixth matching resistor MR₅ is electrically connected to the second voltage V2.

Of the digital-to-analog converter 320, the first resistor R₀, the second resistor R₁, the third resistor R₂, . . . , the sixth resistor R₅ are sequentially connected in serial, wherein the first terminal of the first resistor R₀ is electrically connected to the first voltage V1, and the second terminal of the sixth resistor R₅ is electrically connected to output terminal OUT. The first matching resistor MR₀, the second resistor MR₁, the third resistor MR₂, . . . , the sixth matching resistor MR₅ are sequentially connected in serial, wherein the first terminal of the first matching resistor MR₀ is electrically connected to output terminal OUT, and the second terminal of the sixth matching resistor MR₅ is electrically connected to the second voltage V2.

Of the digital-to-analog converter 330, the sixth resistor R₅, the fifth resistor R₄, the fourth resistor R₃, . . . , the first resistor R₀ are sequentially connected in serial, wherein the first terminal of the fifth resistor R₅ is electrically connected to the first voltage V1, and the second terminal of the first resistor R₀ is electrically connected to output terminal OUT. The sixth matching resistor MR₅, the fifth resistor MR₄, the fourth resistor MR₃, . . . , the first matching resistor MR₀ are sequentially connected in serial, wherein the first terminal of the sixth matching resistor MR₅ is electrically connected to output terminal OUT, and the second terminal of the first matching resistor MR₀ is electrically connected to the second voltage V2.

Compared with the conventional digital-to-analog converter, the digital-to-analog converter disclosed in the above embodiments of the invention has less number of resistors and switches. Besides, the invention has a simple circuit structure, and the n-bit digital-to-analog converter of the invention electrically connects the nodes between any two resistor to n switches and (2n+1) wires, while the conventional n-bit digital-to-analog converter needs 2ⁿ wires and (2ⁿ⁺¹−2) switches. Therefore, the invention largely reduces the area of circuit layout and the cost. Furthermore, as less number of wires is used, a high-bit digital-to-analog converter is easier to be realized.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A digital-to-analog converter for converting a digital signal into an analog voltage, wherein the digital signal comprises a first bit value and a second bit value, the first bit value is a low-bit value, and the digital-to-analog converter comprises:
a first series of resistors electrically connected between a first voltage and an output terminal of the digital-to-analog converter, the first series of resistors comprises at least a first resistor and a second resistor, the resistance of the second resistor is substantially double of that of the first resistor, and the first resistor is serially coupled to the second resistor;
a first cascade of switches comprising at least a first switch and a second switch, wherein the first switch and the first resistor are connected in parallel and so are the second switch and the second resistor connected in parallel, the first switch is controlled by a first control signal corresponding to the first bit value, and the second switch is controlled by a second control signal corresponding to the second bit value;
a second series of resistors electrically connected between a second voltage and the output terminal, wherein the second series of resistors comprises at least a first matching resistor and a second matching resistor, the resistance of the first matching resistor is substantially equal to the resistance of the first resistor, the resistance of the second matching resistor is substantially equal to the resistance of the second resistor, and the first matching resistor is serially coupled to the second matching resistor; and
a second cascade of switches comprising at least a first matching switch and a second matching switch, wherein the first matching switch and the first matching resistor are connected in parallel and so are the second matching switch and the second matching resistor connected in parallel, the first matching switch is controlled by a first matching control signal corresponding to the complementary value of the first bit value, and the second switch is controlled by a second matching control signal corresponding to the complementary value of the second bit value;
wherein the digital-to-analog converter outputs the analog voltage via the output terminal.

2. The digital-to-analog converter according to claim 1, wherein the digital signal further comprises a third bit value, the first series of resistors further comprises a third resistor whose resistance is substantially double of the resistance of the second resistor, the first cascade of switches further comprises a third switch connected in parallel with the third resistor, the third switch is controlled by a third control signal corresponding to the third bit value, the second series of resistors further comprises a third matching resistor whose resistance is substantially equal to the resistance of the third resistor, the second cascade of switches further comprises a third matching switch connected in parallel with the third matching resistor, and the third matching switch is controlled by a third matching control signal corresponding to the complementary value of the third bit value.

3. The digital-to-analog converter according to claim 2, wherein a first terminal of the first resistor is coupled to the first voltage, a first terminal of the second resistor is coupled to a second terminal of the first resistor, a first terminal of the third resistor is coupled to a second terminal of the second resistor, a second terminal of the third resistor is coupled to the output terminal, a first terminal of the third matching resistor is coupled to the output terminal, a first terminal of the second matching resistor is coupled to a second terminal of the third matching resistor, a first terminal of the first matching resistor is coupled to a second terminal of the second matching resistor, and a second terminal of the first matching resistor is coupled to the second voltage.

4. The digital-to-analog converter according to claim 2, wherein the first terminal of the third resistor is coupled to the first voltage, the first terminal of the second resistor is coupled to the second terminal of the third resistor, the first terminal of the first resistor is coupled to the second terminal of the second resistor, the second terminal of the first resistor is coupled to the output terminal, the first terminal of the first matching resistor is coupled to the output terminal, the first terminal of the second matching resistor is coupled to the second terminal of the first matching resistor, the first terminal of the third matching resistor is coupled to the second terminal of the second matching resistor, and the second terminal of the third matching resistor is coupled to the second voltage.

5. The digital-to-analog converter according to claim 2, wherein the first terminal of the first resistor is coupled to the first voltage, the first terminal of the second resistor is coupled to the second terminal of the first resistor, the first terminal of the third resistor is coupled to the second terminal of the second resistor, the second terminal of the third resistor is coupled to the output terminal, the first terminal of the first matching resistor is coupled to the output terminal, the first terminal of the second matching resistor is coupled to the second terminal of the first matching resistor, the first terminal of the third matching resistor is coupled to the second terminal of the second matching resistor, and the second terminal of the third matching resistor is coupled to the second voltage.

6. The digital-to-analog converter according to claim 2, wherein a first terminal of the third resistor is coupled to the first voltage, a first terminal of the second resistor is coupled to a second terminal of the third resistor, a first terminal of the first resistor is coupled to a second terminal of the second resistor, a second terminal of the first resistor is coupled to the output terminal, a first terminal of the third matching resistor is coupled to the output terminal, a first terminal of the second matching resistor is coupled to a second terminal of the third matching resistor, a first terminal of the first matching resistor is coupled to a second terminal of the second matching resistor, and a second terminal of the first matching resistor is coupled to the second voltage.

7. A digital-to-analog converter for converting a digital signal into an analog voltage, wherein the digital signal is expressed as (Bₙ₋₁ . . . B₂ B₁ B₀)₂, and the digital-to-analog converter comprises:
a first series of resistors electrically connected between a first voltage and an output terminal of the digital-to-analog converter, the first series of resistors comprises n resistors R₀, R₁, R₂ . . . Rₙ₋₁ whose resistances are substantially equal to R, 2R, 2²R, . . . 2ⁿ⁻¹R respectively, R is the resistance of the resistor R₀, and the resistors R₀, R₁, R₂, . . . Rₙ₋₁ are connected in serial;
a first cascade of switches comprising n switches SW₀, SW₁, SW₂ . . . SWₙ₋₁, wherein the n switches SW₀, SW₁, SW₂ . . . SWₙ₋₁ and the n resistors R₀, R₁, R₂, . . . Rₙ₋₁ are respectively connected in parallel, and the n switches SW₀, SW₁, SW₂ . . . SWₙ₋₁ are respectively controlled by n control signals corresponding to the bit values B₀, B₁, B₂, . . . Bₙ₋₁;
a second series of resistors electrically connected between a second voltage and the output terminal, the second series of resistors comprises n matching resistors MR₀, MR₁, MR₂, . . . MRₙ₋₁ whose resistances substantially equal to the resistances of the resistors R₀, R₁, R₂, . . . Rₙ₋₁ respectively, and the matching resistors MR₀, MR₁, MR₂, . . . MRₙ₋₁ are connected in serial; and
a second cascade of switches comprising n matching switches MSW₀, MSW₁, MSW₂ . . . MSWₙ₋₁, wherein the n matching switches MSW₀, MSW₁, MSW₂, . . . MSWₙ₋₁ and the n matching resistors MR₀, MR₁, MR₂, . . . MRₙ₋₁ are respectively connected in parallel, the n matching switches MSW₀, MSW₁, MSW₂, . . . MSWₙ₋₁ are respectively controlled by n matching control signals respectively corresponding to the complementary values of the bit values B₀, B₁, B₂, . . . Bₙ₋₁;
wherein the digital-to-analog converter outputs the analog voltage via the output terminal.

8. The digital-to-analog converter according to claim 7, wherein the resistors are connected in serial according to the sequence of R₀, R₁, R₂, . . . Rₙ₋₁, a first terminal of the resistor R₀ is electrically connected to the first voltage, a second terminal of the resistor Rₙ₋₁ is electrically connected to the output terminal, the matching resistors are connected in serial according to the sequence of MRₙ₋₁, MRₙ₋₁, MRₙ₋₂, . . . MR₀, a first terminal of the matching resistor MRₙ₋₁ is electrically connected to the output terminal, a second terminal of the matching resistor MR₀ is electrically connected to the second voltage.

9. The digital-to-analog converter according to claim 7, wherein the resistors are connected in serial according to the sequence of Rₙ₋₁, Rₙ₋₂, Rₙ₋₃ . . . R₀, a first terminal of the resistor Rₙ₋₁ is electrically connected to the first voltage, a second terminal of the resistor R₀ is electrically connected to the output terminal, the matching resistors are connected in serial according to the sequence of MR₀, MR₁, MR₂, . . . MRₙ₋₁, a first terminal of the matching resistor MR₀ is electrically connected to the output terminal, and a second terminal of the matching resistor MRₙ₋₁ is electrically connected to the second voltage.

10. The digital-to-analog converter according to claim 7, wherein the resistors are connected in serial according to the sequence of R₀, R₁, R₂, . . . Rₙ₋₁, a first terminal of the resistor R₀ is electrically connected to the first voltage, a second terminal of the resistor Rₙ₋₁ is electrically connected to the output terminal, the matching resistors are connected in serial according to the sequence of MR₀, MR₁, MR₂ . . . MRₙ₋₁, a first terminal of the matching resistor MR₀ is electrically connected to the output terminal, and a second terminal of the matching resistor MRₙ₋₁ is electrically connected to the second voltage.

11. The digital-to-analog converter according to claim 7, wherein the resistors are connected in serial according to the sequence of Rₙ₋₁, Rₙ₋₂, Rₙ₋₃, . . . R₀, the first terminal of the resistor Rₙ₋₁ is electrically connected to the first voltage, a second terminal of the resistor R₀ is electrically connected to the output terminal, the matching resistors are connected in serial according to the sequence of MRₙ₋₁, MRₙ₋₂, MRₙ₋₃, . . . MR₀, a first terminal of the matching resistor MRₙ₋₁ is electrically connected to the output terminal, and a second terminal of the matching resistor MR₀ is electrically connected to the second voltage.
